(19) United States
(12) Patent Application Publication
(10) Pub. No.: US 2006/0273432 A1
(43) Pub. Date: Dec. 7, 2006

(54) Lead frame with attached components

(75) Inventors: Bernhard Lange, Garland, TX (US); Steven A. Kummerl, Carrollton, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/146,182

(22) Filed: Jun. 6, 2005

(51) Int. Cl. H01L 23/495

(52) U.S. Cl. 257/666

(57) ABSTRACT

According to an embodiment of the invention, a package comprises a lead frame, a first passive component, a first wire bond connection, and a mold compound. The lead frame has a first pair of resilient arms. The first passive component is disposed between the first pair of resilient arms. The first wire bond connection is disposed between the die and a portion of the lead frame adjacent the first passive component. The first wire bond connection is operable for communication between the die and the first passive component. The mold compound is disposed at least partially around the lead frame, the first passive component, the first wire bond connection, and the die.

### TECHNICAL FIELD OF THE INVENTION

This invention relates generally to the field of semiconductor devices and, more particularly, to a lead frame with attached components.

### BACKGROUND OF THE INVENTION

A packaged integrated circuit may generally include semiconductor chips and their associated components embedded within a molding. The packaged integrated circuits may be connected to a printed circuit board of an electronic device. Through the printed circuit board, the packaged integrated circuit may be connected to other chips and to external inputs and outputs. A vertical height of the packaged integrated circuit may generally be limited by the components disposed therein.

### SUMMARY OF THE INVENTION

According to an embodiment of the invention, a package comprises a lead frame, a first passive component, a first wire bond connection, and a mold compound. The lead frame has a first pair of resilient arms. The first passive component is disposed between the first pair of resilient arms. The first wire bond connection is disposed between the die and a portion of the lead frame adjacent the first passive component. The first wire bond connection is operable for communication between the die and the first passive component. The mold compound is disposed at least partially around the lead frame, the first passive component, the first wire bond connection, and the die.

Certain embodiments of the invention may provide numerous technical advantages. For example, a technical advantage of one embodiment may include the capability to utilize standard components in a package without exceeding a vertical height constraint in the package. Other technical advantages of other embodiments may include the capability to utilize standard components in a package without increasing a height of the package, to decrease a vertical height of the package, or to decrease a cost associated with a package having components.

Although specific advantages have been enumerated above, various embodiments may include all, some, or none of the enumerated advantages. Additionally, other technical advantages may become readily apparent to one of ordinary skill in the art after review of the following figures and description.

### BRIEF DESCRIPTION OF THE DRAWINGS

For a more complete understanding of example embodiments of the present invention and its advantages, reference is now made to the following description, taken in conjunction with the accompanying drawings, in which:

FIG. 1 shows a side cross-sectional view representative of a conventional integrated circuit package;

FIG. 2A shows a top cut-away view of a package, according to an embodiment of the invention;

FIG. 2B shows a side cross-sectional view of a package, according to an embodiment of this invention;

FIGS. 3A, 3B, 3C, and 3D show a top view of a side placement of a component within arms of a lead frame, according to an embodiment of the invention;

FIG. 4A shows a side view of a top placement of component within arms of a lead frame, according to another other embodiments of the invention;

FIG. 4B shows a tool that may be utilized to facilitate the top placement shown in FIG. 4A, according to an embodiment of the invention;

FIG. 4C shows the placement of conductive epoxy or soldering between a lead frame, arms, and a component, according to an embodiment of the invention;

FIGS. 5A, 5B, and 5C show top view configurations of arms, according to embodiments of the invention;

FIG. 6A shows a side view of a system, which may be utilized for side placement of a component between arms, according to an embodiment of the invention; and

FIG. 6B shows a side view of a system, which may be utilized for top placement of a component between arms, according to an embodiment of the invention.

### DETAILED DESCRIPTION OF EXAMPLE EMBODIMENTS OF THE INVENTION

It should be understood at the outset that although example embodiments of the present invention are illustrated below, the present invention may be implemented using any number of techniques, whether currently known or in existence. The present invention should in no way be limited to the example embodiments, drawings, and techniques illustrated below, including the embodiments and implementation illustrated and described herein. Additionally, the drawings are not necessarily drawn to scale.

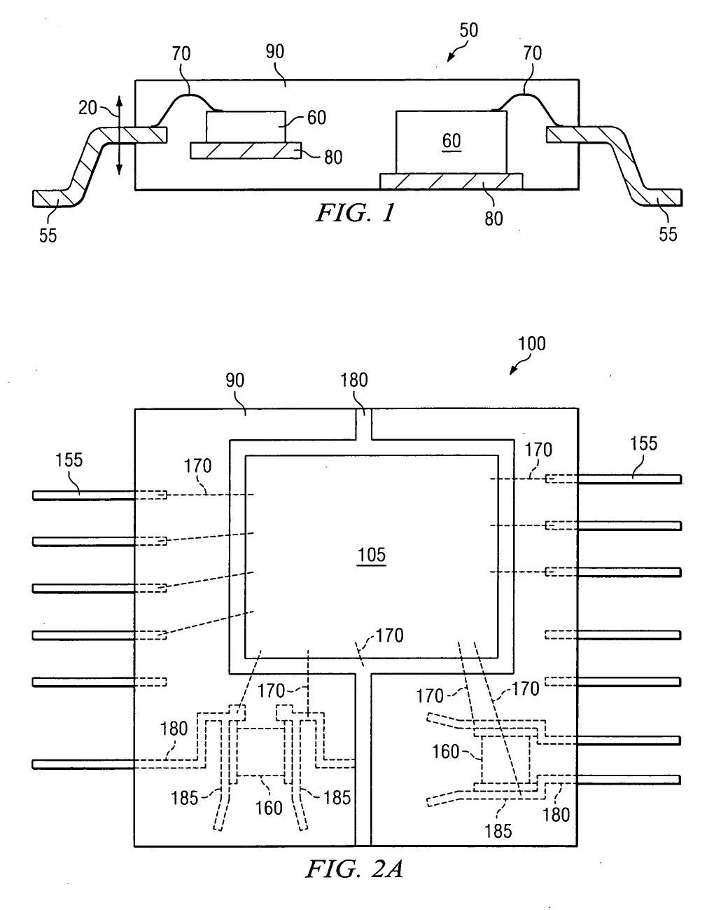

Integrated circuit manufacturers incorporate components (e.g., passive components such as capacitors, inductors, and resistors) within integrated circuit packages. FIG. 1 shows a side cross-sectional view representative of a conventional integrated circuit package 50 with such incorporated components. The semiconductor package 50 generally includes a die (not explicitly shown), components 60, a lead frame 80, wire bond connections 70, and lead pins 55. During manufacture of the integrated circuit package 50, the die and the components 60 are mounted on top of the lead frame 80. The components 60 and/or die are then wire bonded to external lead pins 55 using wire bond connections 70. Finally, the mold compound 90 is placed around die, the components 60, the wire bond connections 70, and a portion of the lead pins 55. The other portion of the lead pins 55 is left extending outside of the mold compound 90 to establish communication with other components, for example, a circuit board, when the semiconductor package 50 is mounted to the circuit board.

The placement of components 60 in an integrated circuit package 50, while desirable, can also lead to several undesirable effects in conventional integrated circuit packages 50. For example, the mounting of components 60 on top of the lead frames 80 (e.g., using conductive epoxy or solder) in the integrated circuit package 50 can undesirably increase a height of the integrated circuit package 50. Additionally, due to a variety of ceiling constraints or vertical height constraints 20 that may be present with the integrated circuit package 50 (e.g., surface mount constraints), a thickness of the components 60 may be constrained. As an example, given a vertical height constraint 20, the maximum allowed thickness of components 60 in the semiconductor package 50 is reduced by a thickness of the lead frame 80 and a clearance needed for the wire bond connections 70. Thus, thinner components 60 must be utilized to allow the components 60 to fit within the integrated circuit package 50.

Thinner components 60 are typically more expensive than standard components, making the integrated circuit package 50 cost prohibitive in certain circumstances. Additionally, in order to bond to the surface of the components 60, the components 60 may require special surfaces that allow bonding—another feature that can increase the cost of the components 60. With such difficulties, teachings of embodiments of the invention recognize a system and method that may allow a reduction of height in packages. Additionally, further teachings of other embodiments of the invention recognize a system and method that may allow utilization of standard-sized sized components without increasing height of the package.

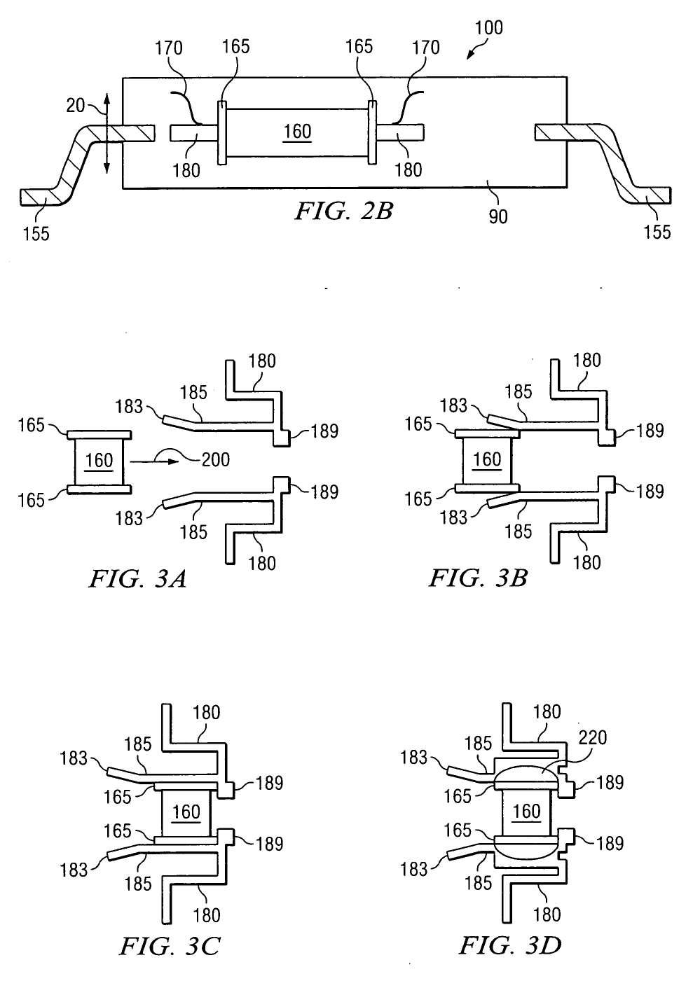

FIG. 2A shows a top cut-away view of a package 100, according to an embodiment of the invention. The package 100 of FIG. 2A includes a lead frame 180, a die 105, wire bond connections 170, one or more components 160, a mold compound 90, and external lead pins 155. In some embodiments, the external lead pins 155 may be an extension of the lead frame 180. Components 160 may include passive components and active components. Examples of passive components include resistors, capacitors, and inductors. Examples of active components include transistors, rectifiers, diodes, amplifiers, oscillators, and integrated circuits. The die 105 may generally provide the foundation for a variety of semiconductor features, including but not limited to, analog and/or digital circuits such as digital to analog converters, computer processor units, amplifiers, digital signal processors, controllers, transistors, or other semiconductor features or other integrated circuits.

Similar to the integrated circuit package 50 above, the external lead pins 155 of the package 100 may extend outside of the mold compound 90 and may be utilized to establish communications between the package 100 and components on a circuit board (not explicitly shown). However, instead of mounting the components 60 to the lead frame 80 as shown in FIG. 1, the components 160 of the embodiment of FIG. 2A are clamped or press fit between arms 185 of the lead frame 180. By clamping or press fitting the components 160 between arms 185 of the lead frame 180, vertical height constraints may be alleviated, allowing the use of standard-sized components instead of thinner components in some embodiments or allowing thinner packages with thinner components in other embodiments. The clamping or press fitting feature of the arms 185 takes advantage of the spring-like resiliency inherent within the lead frame 180 to support or hold the components 160 during a molding process.

In a manner similar to that described above with reference to FIG. 1, the manufacture of the package 100 of FIG. 2A may begin by attaching the die 105 onto the lead frame 180. Although not explicitly shown, the die 105 may be attached to the lead frame 180, utilizing a variety of attachment mediums, including epoxy, polyimide, other adhesive chemistries, mixture of such chemistries, solder, a gold-silicon Eutectic layer, or other suitable material for bonding the die 105 to the lead frame 180. The components 160 may be positioned between the arms 185 before, during, or after the attachment of the die 105 to the lead frame 80. Further details of techniques of positioning the components 160 between the arms 185 will be described below with reference to FIGS. 6A and 6B. After positioning the components 160 and/or die 105 with the lead frame 180, appropriate wire bond connections 170 may be made between the lead frame 180, the die 105, and external lead pins 55 to facilitate appropriate communications. Mold compound 90 may then be placed around the die 105, the lead frame 180, the components 160, the wire bond connections 170, and at least a portion of the lead pins 155.

As can be seen in FIG. 2A, the wire bond connections 170 are not directly bonded to the components 160. Rather, the wire bond connections 170 are coupled or bonded to portions of the lead frame 180 that are adjacent the components 160. The bonding to portions of the lead frame 180 that are adjacent to the components 160 allows communications to be established with the components 160 without direct bonding with the components 160. To facilitate these communications, the components 160 may include terminals 165 (not explicitly shown in FIG. 2A). With the above configuration, components 160 may be utilized that do not require special bonding surfaces, thereby reducing the costs of the components 160 and the package 100 in some embodiments. Further details of these communications will be described below.

To allow the above describe resiliency in the arms 185 and maintain the above communications, the lead frame 180 may be made from a variety of different materials, including, but not limited to, copper, other metallic material, and other suitable materials.

FIG. 2B shows a side cross-sectional view of a package 100, according to an embodiment of this invention. The package 100 of FIG. 2B may be similar to the package 100 of FIG. 2B, including a lead frame 180, a die (not explicitly shown), wire bond connections 170, one or more components 160, a mold compound 90, and external lead pins 155. FIG. 2B illustrates how a clamping or press-fitting in the arms 185 help alleviate a vertical height constraint 20 in the package 100. As an example, the lead frames 180 do not reduce a size of the components 160 because the components 160 are not mounted to the top of the lead frame 180. As briefly described above, utilizing configurations such as this as well as configurations described with various other embodiment of the invention, standard-sized components may be utilized while maintaining vertical height constraints 20. In other embodiments, thin components may be utilized to obtain packages 100 with a thinner height.

FIGS. 3A, 3B, 3C, and 3D show a top view of a side placement of a component 160 within arms 185 of a lead frame 180, according to an embodiment of the invention. The component 160 may be moved in the direction of arrow 200 towards arms 185 as seen in FIG. 3A. To facilitate a positioning of the components between the arms 185, ends 183 of the arms 185 may include a variety of features. For example, in this embodiment, the ends 183 of the arms 185 are bowed out. Upon contacting the arms 185 as seen in FIG. 3B, the continued force of the component 160 in the direction of arrow 200 may slightly widen the arms 185. The arms 185, resisting such motion, hold the component 160 with a spring-like effect. In some embodiments, friction between the arms and the components 160 may vertically support the components 160. In other embodiments, one or both of the components 160 and the arms 185 may include a groove to support the component 160. The component 160 may reach final positioning upon contact with an end stop 189, which may also be utilized as a bond pad. After such final positioning of the component 160, some embodiments may additionally utilize a conductive epoxy or soldering 220 to hold the component 160 in position and help establish electrical conductivity between the component 160 and the lead frame 180.

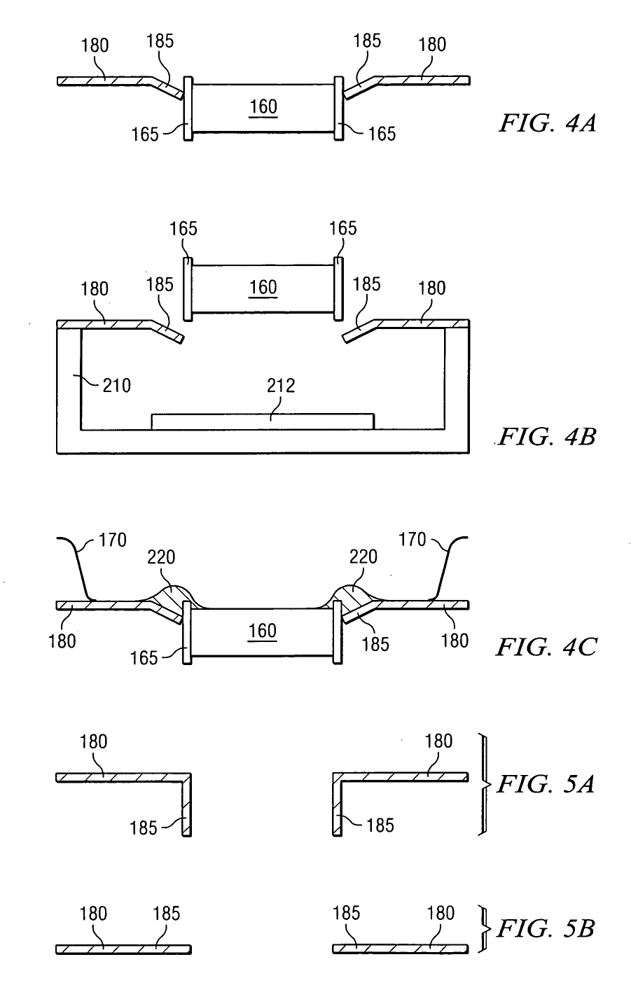

FIG. 4A shows a side view of a top placement of components 160 within arms 185 of a lead frame 180, according to another other embodiments of the invention. Similar to FIG. 3B, the arms 185 of the lead frame 180 may resiliently hold the components 160 in position in a spring-like manner upon insertion of the component 160 between the arms 185 of the lead frame 180.

FIG. 4B shows a tool 210 that may be utilized to facilitate the top placement shown in FIG. 4A, according to an embodiment of the invention. The tool 210 of FIG. 4B includes a base plate 212, which defines a maximum depth of the component 160 with respect to the lead frame 180. For example, upon inserting the component 160 between the arms 185, a downward motion of the component 160 may continue until the base plate 212 is contacted.

FIG. 4C shows the placement of conductive epoxy or soldering 220 between a lead frame 180, arms 185, and a component 160, according to an embodiment of the invention. Similar to FIG. 3D, the conductive epoxy or soldering 220 may facilitate a holding of the component 160 in position between the arms 185. FIG. 4C additionally shows wire bond connections 170 placed on the lead frame 180. As briefly described above, communications with the component 160 may occur through the wire bond connection 170, the lead frame 180 adjacent the component, the arms 185, and the terminals 165 to the component 160 and vice versa.

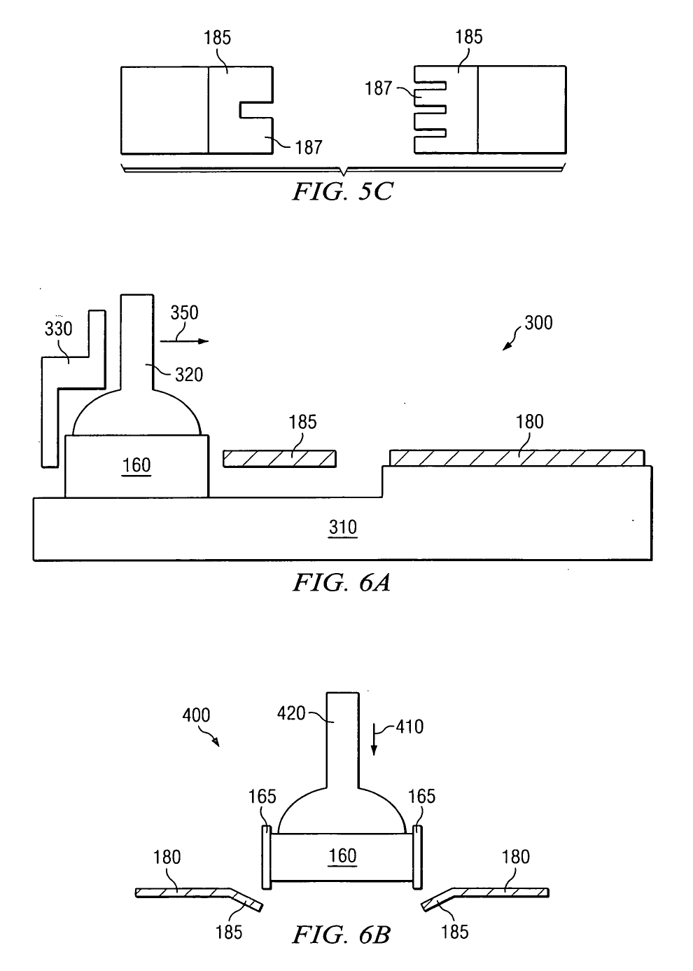

FIGS. 5A, 5B, and 5C illustrate top view configurations of arms 185, according to embodiments of the invention. The embodiment of FIG. 5A shows a ninety-degree angle bend contact area; the embodiment of FIG. 5B shows a straight contact area; and the embodiment of FIG. 5C shows multiple fingers 187 on the arm 185 that may be utilized in contacting the component 160. Although such configurations have been shown, a variety of configurations may additionally be utilized.

FIG. 6A shows a side view of a system 300, which may be utilized for side placement of a component 160 between arms 185, according to an embodiment of the invention. The system 300 of FIG. 6A includes a support block 310, a vacuum nozzle 320, and a height variable push block 330. In operation, the lead frame 180, including the arms 185, may be placed upon on the support block 310. The vacuum nozzle 320 may pick up the component 160 and the push block 330 may push the component 160 between the arms 185, for example, in the direction of arrow 350. When the component 160 is secured between the arms 185, the vacuum nozzle 320 may release the component 160. The height variability of the push block 330 allows the system 300 to account for various sizes of components 160.

FIG. 6B shows a side view of a system 400, which may be utilized for top placement of a component 160 between arms 185, according to an embodiment of the invention. Similar to FIG. 6A, the system 400 of FIG. 6B includes a vacuum nozzle 420. The vacuum nozzle 420 may push the component in the direction of arrow 410 for insertion between the arms 185. The system 400 may additionally utilize conventional surface mount device (SMD) equipment for a top placement of a component 160 between the arms 185.

Although the present invention has been described with several embodiments, a myriad of changes, variations, alterations, transformations, and modifications may be suggested to one skilled in the art, and it is intended that the present invention encompass such changes, variations, alterations, transformation, and modifications as they fall within the scope of the appended claims.

1. A package comprising:
a lead frame having a first pair of resilient arms;
a first passive component clamped between the first pair of resilient arms;
a die coupled to the lead frame;
a first wire bond connection disposed between the die and the lead frame adjacent the first passive component, the first wire bond connection operable for communication between the die and the first passive component; and
a mold compound covers at least partially the lead frame, the first passive component, the first wire bond connection, and the die.

2. The package of claim 1, wherein the lead frame has a second pair of resilient arms and lead pins, further comprising:
a second passive component clamped between the second pair of resilient arms; and
a second wire bond connection disposed between the die and the lead frame adjacent the second passive component, the second wire bond connection operable for communication between the die and the second passive component; and
a third wire bond connection disposed between the die and lead pin, the third wire bond connection operable for communication between the die and components external of the package.

3-14. (canceled)

15. A package comprising:
a lead frame, having a first pair of resilient arms;
a first component clamped between the first pair of resilient arms;
a die disposed on the lead frame; and
a mold compound covering the lead frame, the die, and the first component.

16. The package of claim 15, wherein the first component is a first passive component.

17. The package of claim 16, further comprising:
a first wire bond connection disposed between the die and the lead frame adjacent the first passive component, the first wire bond connection operable for communication between the die and the first passive component.

18. (canceled)

19. The package of claim 15, wherein the lead frame further comprises a second pair of resilient arms, further comprising:
a second component clamped between the second pair of resilient arms.

20. The package of claim 19, further comprising:
a first wire bond connection disposed between the die and the lead frame adjacent the first component, the first wire bond connection operable for communication between the die and the first component; and
a second wire bond connection disposed between the die and the lead frame adjacent the second component, the second wire bond connection operable for communication between the die and the second component.

21. A package comprising:
a lead frame having a first pair of resilient arms and a second pair of resilient arms;
a first passive component clamped between the first pair of resilient arms;
a second passive component clamped between the second pair of resilient arms; and
conductive material disposed at the vicinity of the first and the second passive component, electrically connecting the first and the second passive component to the lead frame.

22. The package of claim 21, in which the conductive material includes epoxy.

23. The package of claim 21, in which the conductive material includes solder.
